(19) United States
(12) Patent Application Publication
(10) Pub. No.: US 2005/0126619 A1
(43) Pub. Date: Jun. 16, 2005

(54) Solar cell module and manufacturing method thereof

(75) Inventors: Takao Abe, Annaka-shi (JP); Hiroyuki Ohtsuka, Annaka-shi (JP)

Correspondence Address: OLIFF & BERRIDGE, PLC, P.O. BOX 19928, ALEXANDRIA, VA, 22320, US

(73) Assignees: SHIN-ETSU HANDOTAI CO., LTD, TOKYO 100-0005 (JP); SHIN-ETSU CHEMICAL CO., LTD, TOKYO 100-0004 (JP)

(21) Appl. No.: 10/505,570

(22) PCT Filed: Nov. 8, 2002
(86) PCT No.: PCT/JP02/11648

(30) Foreign Application Priority Data
Feb. 28, 2002 (JP) 2002-53882

(51) Int. Cl. H01L 25/00

(52) U.S. Cl. 136/244; 136/246; 438/80

(57) ABSTRACT

First cells 10, obtained by cutting each of disk-formed solar battery cells at cutting positions set in parallel on the main surface thereof symmetrically with respect to the center line which halves the main surface, are arranged in parallel and staggered manner to thereby fabricate a solar battery module 100. Also two segments of by-produced second cells 20R and 20L are paired so as to oppose both cut edges, and a plurality of thus-obtained pairs are arranged to thereby produce a solar battery module 101. This makes it possible to reduce loss of disk-formed wafers, and to raise the module-packing ratio higher than that in the case where the disk-formed cells are arranged in an intact form. This is successful in providing solar battery modules and a method of fabricating the same capable of raising the module-packing ratio while reducing the loss of single crystal wafer to be used.

### BACKGROUND OF THE INVENTION

1. Field of the Invention

This invention relates to a solar battery module configured by arranging a plurality of solar battery cells produced using semiconductor single crystal substrates, and a method of fabricating the same.

2. Description of the Related Art

Solar battery cells using semiconductor single crystal wafers are the mainstream of the solar battery currently disseminated, because they have a higher energy conversion efficiency as compared with that of cells using polycrystal or amorphous wafers, and also because the semiconductor single crystal wafers are relatively inexpensive.

The single crystal wafers, typically obtained by slicing a semiconductor single crystal manufactured by Czochralski method (simply referred to as the CZ method, hereinafter) or by the floating zone method (simply referred to as the FZ method, hereinafter), generally have a disk form. Assuming now that a ratio of area occupied by the solar battery cells to the total module area as module-packing ratio, a high level of module-packing ratio cannot be achieved simply by two-dimensionally arranging the disk-formed solar cells while keeping their wafer form, or in their intact disk form.

In order to improve a substantial energy conversion efficiency on the basis of the module area, it is necessary to raise the module-packing ratio. One general and well-known method of increasing the module-packing ratio is such as processing the solar cell batteries into a square form. The method is, however, disadvantageous in that cutting of a disk-formed semiconductor single crystal wafer so as to obtain a square-formed cell results in crystal loss.

To solve these problems in the module-packing ratio and crystal loss, a proposal has been made on producing hexagonal solar battery cells (see U.S. Pat. No. 4,089,705). This method might reduce the crystal loss as compared with the aforementioned case of square-formed cells, but still cannot exempt from causing the crystal loss, and further raises problems in that the hexagonal processing is labor-consuming, and that the hexagonal shape prevents automated apparatuses generally used for LSI device process from being directly adopted.

It is therefore an object of this invention to provide solar cell modules and a method of fabricating the same, capable of avoiding loss of single crystal wafer to be used, adopting apparatuses generally used for LSI device process, and raising the module-packing ratio as compared with the case where disk-formed cells are arranged without modification.

### DISCLOSURE OF THE INVENTION

As a solution to the aforementioned subject, a method of fabricating solar battery modules comprises the steps of divisionally producing two or more types of segments differing in the shape from each other from each of disk-formed solar battery substrates, respectively collecting the same types of the segments, and two-dimensionally arranging the segments, by types, to thereby obtain respective solar battery modules.

More specifically, all portions of each solar battery substrate can divisionally be produced so as to make them belong to any one of the types of the segments. In other words, the semiconductor single crystal wafers before the cell formation process can completely be consumed up without causing residual portion, and do not cause crystal loss (excluding a portion consumed as a cutting width during segmentation using a cutting blade or the like).

Any processing for forming the solar battery cells (cell formation process) may of course be carried out after the semiconductor single crystal wafers are divided, but is more preferably targeted at semiconductor single crystal before being divided. In other words, it is preferable to carry out the cell formation process respectively in the areas planned to be included later in the segments, and to divide the wafers after completion of the cell formation process. This process needs a separate pattern for cell formation for every planned area to be divided, but the cell formation process per se can be proceeded over the entire area of the wafer at a time, so that the solar battery modules can be fabricated by applying apparatuses similar to the conventional ones without any modification. In this case, the semiconductor single crystal wafers to be subjected to the cell formation process are preferably such as those being chamfered on the outer circumference thereof, similarly to wafers used for LSI device process. This makes it possible to reduce fraction defective such as cracking, chipping and so forth in the cell formation process, as compared typically with conventional square wafers subjected to the cell formation process without being chamfered.

One exemplary method of obtaining the segments divisionally produced from the disk-formed solar battery substrate is such as setting, as planned cutting lines, one pair or two or more pairs of parallel lines (referred to as parallel planned cutting lines, hereinafter) symmetrically arranged with respect to the center of the wafer on a main surface of the semiconductor single crystal wafers; subjecting the semiconductor single crystal wafers to the cell formation process respectively for a first segment forming area including the center of the wafer and for bow-formed second segment forming areas, which are the residual area besides the first segment forming area, to thereby form the solar battery cells; and cutting the solar battery cell along the planned cutting lines in the thickness-wise direction thereof. The first segments, which are major segments having a larger area, are of course used for fabrication of the solar battery module, but a most essential feature of this invention resides in that also the second segments, which have been understood merely as a fragment having a smaller area, and have simply been thought as being of no use other than being discarded (or rather, they are intrinsically of no interest after the first segments are picked up). Cutting of the wafer at parallel cutting positions spaced by a predetermined distance is advantageous also in that there is no need of using any special apparatuses and programs, and in that any automated apparatuses used for the conventional device process can be adopted without modification.

For the case where the solar battery cell is divided into the first segment and second segment, too small area of the second segment results in an extremely large number of segments for composing a single solar battery module, and consequently in an increased number of process steps and costs. It is therefore preferable to limit the size of the second segment to an appropriate range relative to the size of the disk-formed solar battery cell to be used, which is typically from 10 to 30% of the size of the first segment.

In view of reducing the number of process steps, it is preferable to set only one pair of parallel planned cutting lines on the first main surface of the semiconductor single crystal wafer. In this case, it is convenient, as shown in FIG. 4, to determine the distance between each of the parallel planned cutting lines and the center of the wafer as R/2, where R is the radius of the disk-formed first main surface, because this makes it possible to make the total area of two second segments closer to the area of the first segment, to handle the second segments to be connected in parallel as one pair having various cell constants equivalent to those of the first segment, and to handle the first segment and second segment on a common design basis.

Using the first segments obtained by the aforementioned fabrication method, a first mode of embodiment of the solar battery module of this invention can be realized as follows. More specifically, the solar battery module is configured as having solar battery segments arranged in a parallel and staggered manner, each of the segments having a shape remained after cutting the disk-formed solar battery cell along a pair of parallel planned cutting lines symmetrically set with respect to the center of the main surface of the solar battery cell, so as to remove a pair of bow-formed segments from the outer periphery portions, and the segments being arranged so that the parallel cut edges thereof are adjacent to each other.

In the solar battery module of the first mode of embodiment, the first segment to be used has the parallel cut edges, and the arrangement in which the edges are adjacent to each other makes it possible to arrange the adjacent first segments over a relatively long distance. This is successful in achieving a far more larger module-packing ratio as compared with the case where the disk-formed solar battery cells are arranged in their intact form. This embodiment is also advantageous in that the cutting process, which is to produce only a single pair of the parallel cut edges, is simpler than that for the case where hexagonal or square segments must be produced.

On the other hand, it is also allowable to determine two or more pairs of parallel planned cutting lines on the first main surface of the semiconductor single crystal wafer. Only a single pair of parallel planned cutting lines can certainly improve space-filling ratio by the first segments in the module. However in pursuit of an ideal space filling, the first segments are still causative of loss of space-filling ratio due to a pair of arc-formed circumferential portions remained in their shape. In view of optimizing the space-filling ratio, it may be necessary to arrange the first segments so that the arc-formed circumferential portions thereof are staggered, whereas the staggered arrangement of the segments of an identical shape on a rectangular or square module panel raises another problem of periodically causing a large dead space in the segment arrangement along the panel edge. Determining now two pairs of the parallel planned cutting lines on the first main surface of each of the semiconductor single crystal wafers, the first segments will have a rectangular form, square form or quadrilateral form resemble thereto. In this case, an arrangement of the first segments in the closest packing can be realized by arranging them in the direction of at least one of two pairs of parallel cut edges produced along the parallel planned cutting lines (e.g., orthogonal lattice arrangement), without following the staggered arrangement. This successfully reduces the loss in the space-filling ratio by the segments in the module.

It is now obvious that the cutting of the disk-formed solar battery cell along the aforementioned parallel planned cutting lines produces two bow-formed congruent second segments on both sides of the first segment. A second mode of embodiment of the solar battery module of this invention is characterized by having a plurality of segment pairs arranged in a staggered manner, each of the segment pairs being composed of bow-formed segments having a planar form congruent with each other and being opposed on the chord-like edges thereof, and in a manner so that the chord-like edges are in parallel to each other.

The second mode of embodiment can be fabricated by using portions of the single crystal substrate not used in the aforementioned first mode of embodiment, that is, by using the second segments. In other words, the second segments obtained by cutting the solar battery cells are paired so as to oppose both cut edges, and a plurality of thus-obtained segment pairs are arranged in a staggered manner.

A third mode of embodiment of the solar battery module of this invention is characterized by having a plurality of bow-formed segment having a planar form congruent with each other, the segments are arranged to form a first-type segment array in which a plurality of segments are unidirectionally arranged so that the chord portion thereof is neighbored on the arc portion of every adjacent segment, and also to form a second-type segment array in which a plurality of segments are arranged so that the direction of the arrangement of the chord portion and arc portion is inverted from that in the first-type segment array, and the first-type segment array and the second-type segment array are alternately arranged so that the end portions in the chord-wise direction of every segment in the second-type segment array is housed in every recessed portion formed between the chord portion of one segment and the arc portion of every adjacent segment in the first-type segment array.

The third mode of embodiment of the solar battery module can be fabricated by forming the first-type segment array in which a plurality of second segments are unidirectionally arranged so that the cut edge which corresponds to the chord portion of the second segment is neighbored on the arc portion of every adjacent second segment, by forming a second-type segment array in which a plurality of second segments are arranged so that the direction of the arrangement of the chord portion and arc portion is inverted from that in the first-type segment array, and by alternately arranging the first-type segment array and the second-type segment array so that the end portions in the chord-wise direction of every second segment in the second-type segment array is housed in every recessed portion formed between the chord portion of one second segment and the arc portion of every adjacent second segment in the first-type segment array.

In either configuration described in the above, the arc-formed second segments are equivalent to each other both in the area and shape, and therefore can function as solar batteries having an almost equal internal resistance. This makes it possible to readily match the output current among the solar batteries to be connected in series for the module making, and therefore to fabricate the solar battery modules having a desirable efficiency. Formation of the first segments in square is advantageous also in that the equivalent bow-formed second segments are produced in two pairs at a time.

If the module composed only of the first segments and the module composed only of the second segments are used in combination for solar power generation, it is possible to improve an average module-packing ratio as compared with that of the module having only the disk-formed solar battery cells having an equal area arranged therein based on the closest packing. This results in an effect substantially equivalent to that the energy conversion efficiency of the element is improved. Assuming now that only one pair of parallel planned cutting lines are set, and that the distance between each of the parallel planned cutting lines and the center of the wafer is set to R/2, calculation of an average of space-filling ratios of the above-described module of the first embodiment and the module of the second embodiment obtained from a single type of disk-formed cells reveals that the module-packing ratio is improved by approximately 4 to 5% as compared with that of the module having the disk-formed cells of an identical area arranged therein based on the closest packing (this will be detailed later).

In this invention, the cutting of the semiconductor single crystal wafer for producing the segments is preferably carried out using a dicer (diamond blade or laser cutting) which is generally used in LSI fabrication process. In the conventional solar battery formation process, a square cell, for example, has been sliced using a peripheral cutting edge, but this has resulted in only an insufficient accuracy in the cutting. (±0.5 mm or around), and has failed in obtaining a module having a dense cell arrangement. On the contrary, use of the dicer capable of ensuring an accuracy of cutting of several micrometers to several tens micrometers makes it possible not only to fabricate a module having a dense cell arrangement with a cell gap of 1 mm or below, or further 500 μm or below, but also to facilitate automated arrangement operation of the cells.

### BRIEF DESCRIPTION OF THE DRAWINGS

FIG. 1 is a flow sheet showing exemplary process steps of fabricating the solar battery module of this invention;

FIG. 2 is a schematic view showing an exemplary sectional structure of a silicon-single-crystal-base solar battery;

FIG. 3 is a perspective view showing an exemplary mode of electrode formation on the light-receiving surface of the silicon-single-crystal-base solar battery;

FIG. 4 is a schematic drawing for explaining a method of cutting the first segment and the second segments from a single silicon single crystal wafer;

FIG. 5A is a schematic plan view showing an essential portion of a solar battery module fabricated by arranging only the first segments;

FIG. 5B is an overall view of the module shown in FIG. 5A;

FIG. 6A is a drawing for explaining dimension of the second segments;

FIG. 6B is a schematic plan view showing a solar battery module fabricated by arranging only the second segments;

FIG. 7 is a conceptual drawing of a texture structure;

FIG. 8 is a schematic plan view for explaining a first modified example of a method of dividing the first segment and the second segments;

FIG. 9 is a schematic plan view showing an exemplary solar battery module using the first segments shown in FIG. 8;

FIG. 10 is a schematic plan view showing an exemplary solar battery module using the second segments shown again in FIG. 8;

FIG. 11 is a schematic plan view for explaining a second modified example of a method of dividing the first segment and the second segments;

FIG. 12 is a schematic plan view showing an exemplary solar battery module using the first segments shown in FIG. 11;

FIG. 13 is a schematic plan view showing an exemplary solar battery module using the second segments shown again in FIG. 11;

FIG. 14 is a drawing schematically showing a sectional structure of a solar battery segment having the OECO structure;

FIG. 15 is a schematic plan view showing an exemplary division of the solar battery cell having the OECO structure into a square-formed first segment and bow-formed second segments;

FIG. 16 is a schematic plan view showing an exemplary solar battery module using the first segments shown in FIG. 15;

FIG. 17 is a schematic plan view showing an exemplary solar battery module using the second segments of one type out of two types thereof shown again in FIG. 15;

FIG. 18 is a schematic plan view showing an exemplary solar battery module using the second segments of the other type out of two types thereof shown again in FIG. 15; and

FIG. 19 is a schematic plan view showing another example of the solar battery module using the second segments.

### BEST MODES FOR CARRYING OUT THE INVENTION

The following paragraphs will describe best modes for carrying out this invention making reference to the attached drawings.

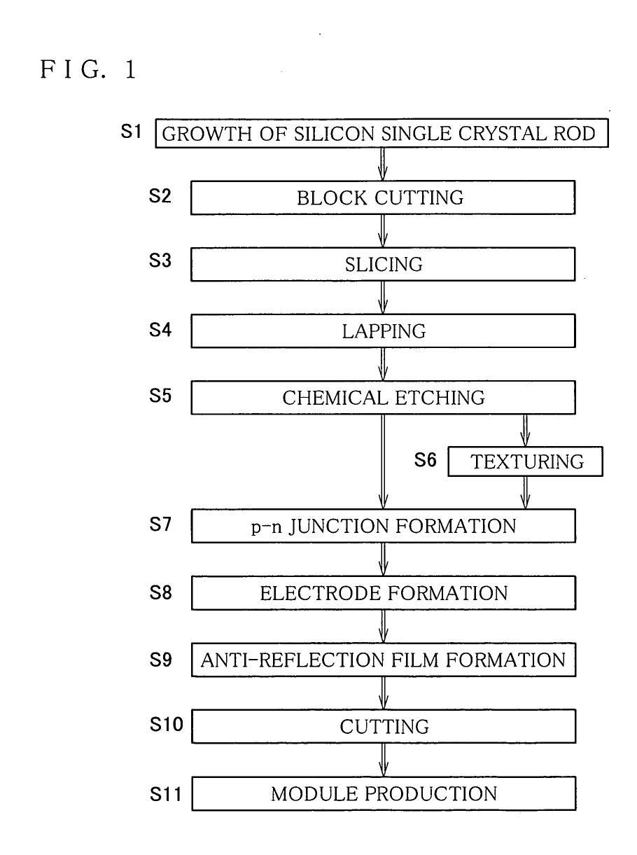

FIG. 1 is a flow sheet showing exemplary process steps of fabricating the solar battery modules of this invention. The process steps of fabricating the solar battery modules is roughly classified into a step of fabricating single crystal wafers which serve as the substrates, and a step of fabricating the solar battery cells (segments).

The step of fabricating single crystal wafers which serve as the substrates will be briefed below. The semiconductor single crystal wafer for producing solar batteries are generally silicon single crystal wafers. The silicon single crystal wafers can be obtained by slicing a single crystal rod obtained by the CZ method or FZ method. First, the silicon single crystal rod herein is fabricated by the CZ method (FIG. 1: S1). The silicon single crystal rod grown herein is added with gallium or boron, for example, to thereby adjust the conductivity type thereof to p type.

Thus-obtained single crystal ingot is then cut into blocks having a predetermined range of resistivity (FIG. 1: S2), and further sliced to a thickness of as thin as 300 μm for example (FIG. 1: S3). Each of the silicon single crystal wafers (simply referred to as wafer, hereinafter) obtained after the slicing is chamfered if necessary, and then lapped using free abrasive grains (FIG. 1: S4). The wafer is then dipped in an etching solution so as to chemically etch both main surfaces (FIG. 1: S5). The chemical etching step is provided in order to remove any damaged layers produced in the surficial portion of the silicon single crystal wafers during the mechanical process steps from S2 to S4. The removal of the damaged layers by the chemical etching is carried out by an acid etching using an aqueous mixed acid solution typically containing hydrofluoric acid, nitric acid and acetic acid. It is to be noted that the lapping in step S4 is often omitted for the wafers fabricated as the substrates for forming the solar battery cells, and that the etching process in step S5 and texturing process in step S6 may sometimes be combined.

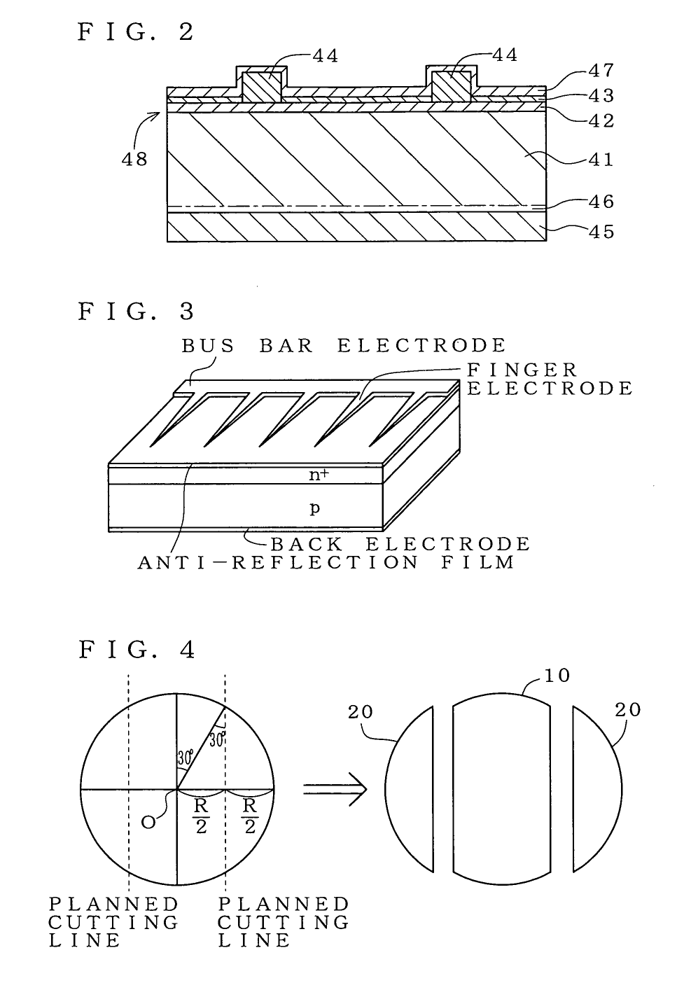

To the silicon single crystal wafer undergone all processes up to the chemical etching (FIG. 1: S5), an n-type dopant diffused layer 42 is formed on the first main surface side to thereby form a p-n junction portion 48 as shown in FIG. 2 (FIG. 1: S7). The depth of the p-n junction 48 from the main surface of the wafer 41 is generally adjusted to 0.5 μm or around. The n-type dopant diffused layer 42 is formed by allowing phosphorus (P), for example, to disperse from the main surface of the p-type silicon single crystal wafer.

On the wafer 41 having the p-n junction portion 48 formed thereon, an oxide film 43 is formed on the first main surface thereof, an electrodes 44 and 45 are formed on the first main surface and second main surface, respectively, and thereby a disk-formed solar battery cell is produced (FIG. 1: S8). Because the solar battery cell is later cut into solar battery segments differing in the shape, so that it is necessary to form the electrode on the first main surface considering the shape of the segments obtained after the cutting. One possible method is such as setting a pair of parallel linear planned cutting lines (see FIG. 4) on the first main surface symmetrically with respect to the center point O of the wafer 41, so as to discriminate the first segment region containing the center point O and the adjacent bow-formed second segment regions on both sides of the first segment region bounded by the planned cutting lines, and carrying out the cell formation process respectively for these segment regions.

After the formation of the electrodes, an anti-reflecting film 47 for reducing light energy loss due to reflection of light is formed on the first main surface side (FIG. 1: S9), and thereby a solar battery cell is produced while keeping the shape of the disk-formed silicon single crystal wafer.

The electrode on the first main surface (light receiving surface) side shown in FIG. 2 typically has a form of finger electrode as shown in FIG. 3, which additionally has wide bus bar electrodes for reducing the internal resistance, provided at appropriate intervals. In contrast to this, the electrode 45 on the second main surface is formed so as to cover the nearly entire surface (FIG. 3; back electrode). On the other hand, the anti-reflection film 47 is composed of a transparent material having a refractive index different from that of silicon.

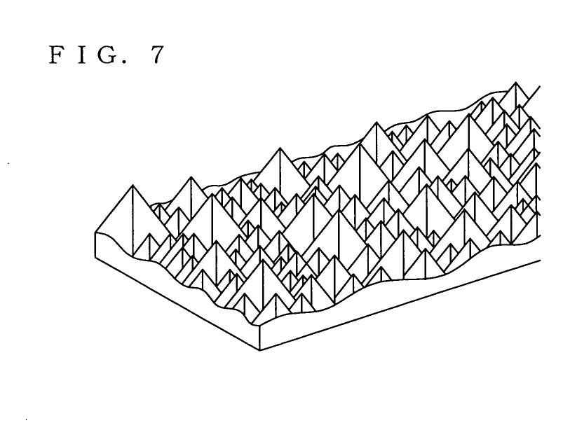

Any flat light-receiving surface may be more or less causative of reflection of light even covered with the anti-reflection film 47, but the reflection can further be suppressed by forming, after the chemical etching step, a texture structure composed of a large number of pyramid-formed projections exposing (111) surface on the first main surface as shown in FIG. 7 (FIG. 1: S6). This type of texture structure can be obtained by anisotropically etching the (100) surface of silicon single crystal using an etching solution such as an aqueous hydrazine solution or sodium hydroxide solution. For the case where the thinning of the substrate is desired to reduce the cell weight, it is allowable, as shown in FIG. 2, to form a back high concentration layer 46 having the same conductivity type with the substrate 41 but a higher concentration, on the second main surface side for the purpose of avoiding recombination and annihilation of minority carriers in the electrode 45 on the second main surface side.

The solar battery cell thus obtained has a disk form keeping the original shape of the wafer 41. This is cut using the dicer along the planned cutting lines in the thickness-wise direction with a desirable accuracy, to thereby divide it into the first segment 10 and two pieces of second segments 20, 20, differing in shape and having the electrodes preliminarily formed thereon according to the predetermined regions, as shown in FIG. 4 (FIG. 1: S10). Assuming that the wafer 41 obtained from a CZ silicon single crystal of 200 mm in diameter is adopted in this invention, the first segment 10 containing the center point O has an area of ca. 191.3 cm², and each of the second segments 20, 20 having no center point O has an area of ca. 61.37 cm². It is also allowable to first cut the wafer 41 into desired shapes and resultant pieces of the wafer 41 are subjected to the cell formation process.

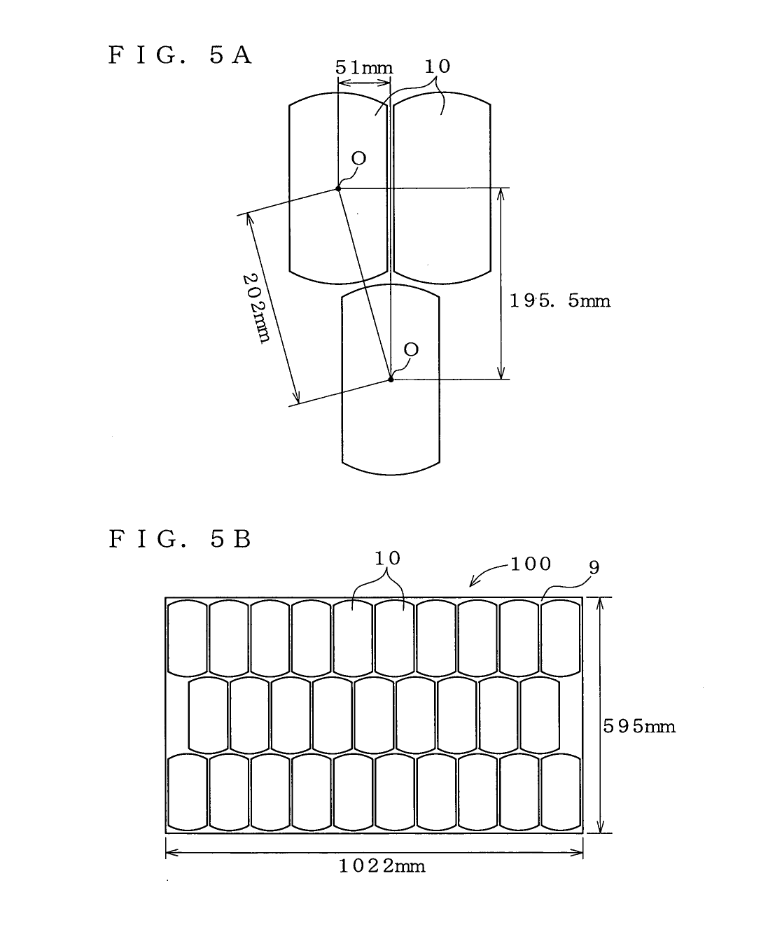

Next, only the first segments 10 are collected and arranged so as to maximize the module-packing ratio. FIG. 5B shows an exemplary arrangement of 29 first segments 10 obtained from 29 slices of 200-mm-diamter silicon single crystal wafers. The module 100 is configured as having the first segments 10 arranged therein in a parallel and staggered manner, so as to neighbor the parallel cut edges thereof (chord-like edge) with each other.

The solar battery module 100 has a rectangular shape which measures 595 mm×1022 mm. As illustrated in FIG. 5A, a gap between every adjacent cells, and a minimum distance between the cell and an edge of a frame on which the cells are placed are equally set to 2 mm. Assuming now that (module-packing ratio)=(occupied area of solar battery cells)/(occupied area of module), the packing ratio of the solar battery module 100 is calculated as approximately 91.2%.

The packing ratio can further be increased by reducing the cell gap to as narrow as 1 mm, for example.

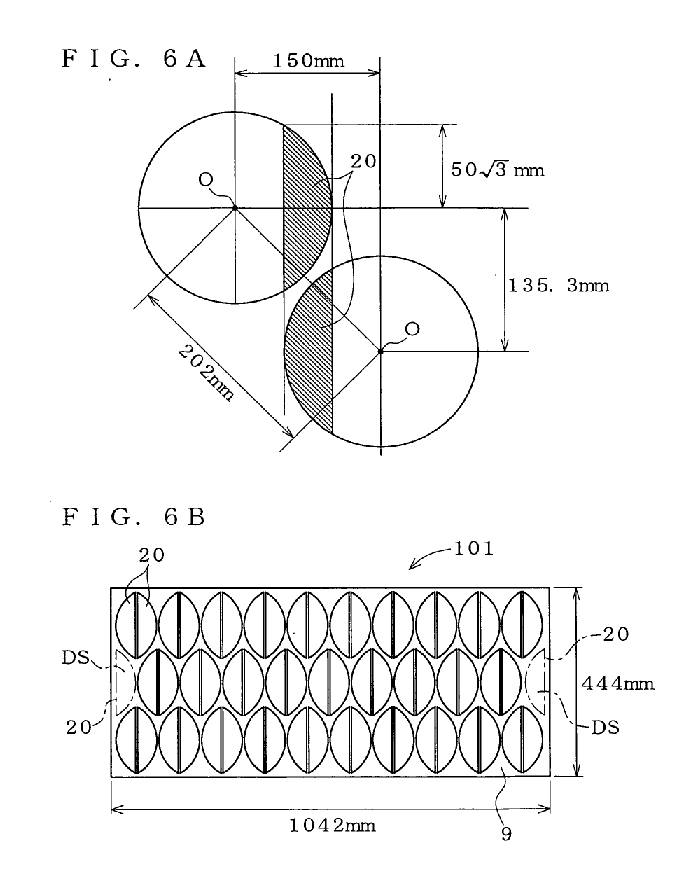

On the other hand, the bow-formed second segments 20, 20 are paired so as to oppose both cut edges, and a plurality of thus-obtained pairs are arranged so as to maximize the module-packing ratio as possible. FIG. 6B shows an exemplary arrangement of 29 pairs of second segments 20, 20 obtained from 29 slices of 200-mm-diamter silicon single crystal wafers 41 similarly to the case of the solar battery module 100 shown in FIG. 5B. The module 101 is configured as having pairs of the second segments 20, 20 arranged therein in a parallel and staggered manner.

The solar battery module 101 has a rectangular shape which measures 444 mm×1042 mm. Similarly to the foregoing case, a gap between every adjacent cells, and a minimum distance between the cell and an edge of a rectangular (or square) module plate (frame) 9 on which the cells are placed are equally set to 2 mm (FIG. 6A). The packing ratio of the solar battery module 101 is calculated as approximately 77.2%. It is to be noted that the staggered arrangement can be affected by a shift between the arrays of the second segments 20, 20, and tends to cause a relatively large dead space DS in every two arrays along the edge of the plate 9 at the end positions in the direction of shifting. The situation is the same also in the module shown in FIG. 5B in which the first segments 10 are arranged in a staggered manner. The module shown in FIG. 6B is, however, more advantageous because a unit of the staggered arrangement is composed of two second segments 20, 20, and this allows only one second segment 20 to fill the dead space DS as indicated by the dashed line. This is successful in further raising the module-packing ratio to as large as 79.8%.

The total packing ratio of the first and second solar battery modules configured as shown in FIG. 5B and FIG. 6B, respectively, is calculated as approximately 85.2% (86.2% under filling of the dead space DS). In contrast to this, arrangement of 29 slices of disk-formed solar battery cells, kept in a disk form without division, in three arrays similarly to as shown in FIG. 5B and FIG. 6B results in a 553 mm×2022 mm module having a larger aspect ratio, which gives a packing ratio of approximately 81.4% (not illustrated). That is, the modules shown in FIG. 5B and FIG. 6B according to this invention are superior in the packing ratio by nearly 4% (5% under filling of the dead space DS) on the total basis.

Combination of the modules shown in FIG. 5B and FIG. 6B is also advantageous on the practical basis because a module having a nearly-square shape can be configured. Any similar nearly-square module configured by using 29 slices of the disk-formed solar battery will further lower the module-packing ratio. This invention is therefore successful in increasing the degree of freedom of selecting module shapes while keeping a high level of module-packing ratio.

In contrast to this, if 29 slices of the disk-formed solar battery cells are divided into two modules respectively comprising 14 slices (three-row, 5-4-5-slice arrangement) and 15 slices (three-row, 5-5-5-slice arrangement), the former results in a 553 mm×1012 mm module and the latter results in a 553 mm×1113 mm module, showing the module shapes equivalent to those in this invention, but results in module-packing ratios of approximately 78.6% and approximately 76.6%, giving a total packing ratio of two modules of 77.5%. It is obvious that the modules shown in FIG. 5B and FIG. 6B, which are the embodiments of this invention, can give the total packing ratio larger by as much as 7.5%.

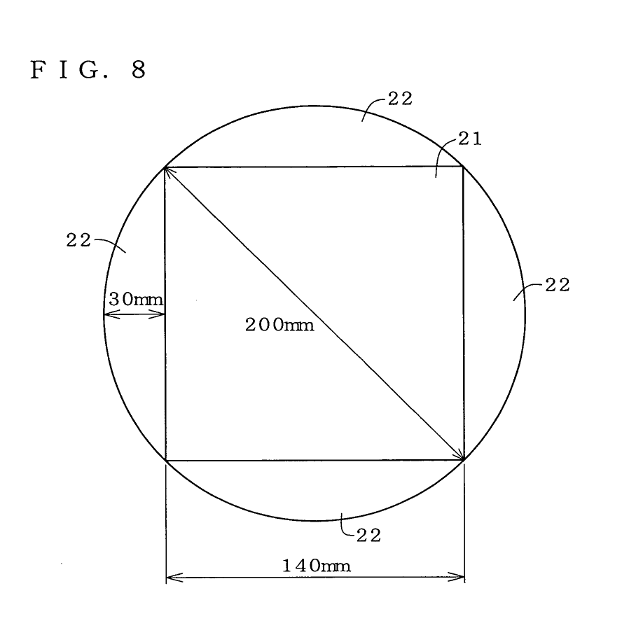

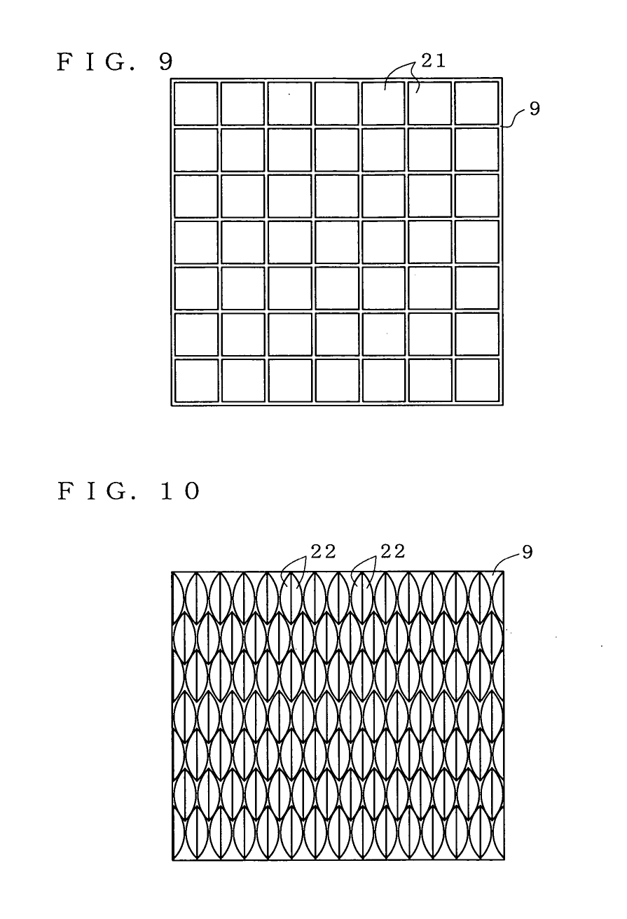

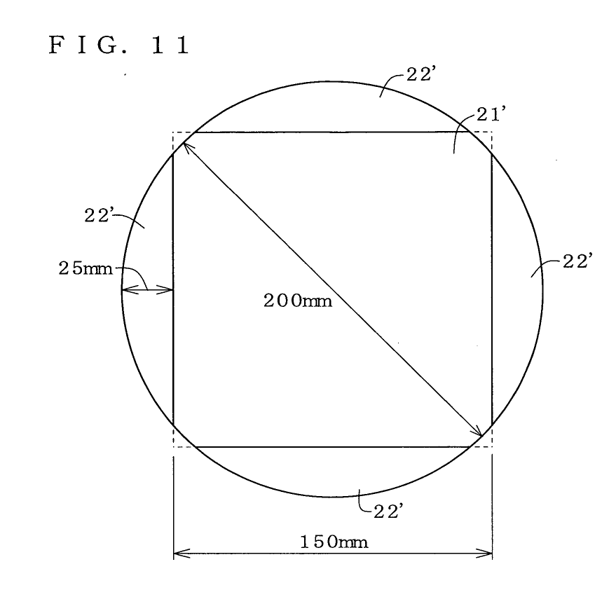

Next, as shown in FIG. 8, it is also allowable to set two pairs of parallel planned cutting line on the disk-formed solar battery cell so as to produce the first segment 21 in a square form. FIG. 8 shows an exemplary case where the first segment 21 having a 140-mm square shape is formed so as to nearly inscribe the 200-mm-diameter solar battery cell. This case produces four pieces of bow-formed second segments 22. The first segment 21 can typically be arranged on the plate 9 in a lattice manner so as to configure the solar battery module as shown in FIG. 9, wherein the segment arrangement while keeping a gap between the plate edge and the first segment, and a gap between the adjacent first segments set equally to 2 mm results in a space-filling ratio of the module of as large as 97% or around. On the other hand, the second segments 22 can be configured as a solar battery cell module as shown in FIG. 10, which follows an arrangement similarly to as shown in FIG. 6 (dead spaces occurring along the plate edge are filled with the unpaired second segments 22). The module has a space-filling ratio of approximately 80%. The average packing ratio of the both is thus given as approximately 89%, which is improved by 7.6% from that (approximately 81.4%) of the module having the disk-formed solar battery cells arranged therein.

Because the cell gap can be narrowed to as small as 1 mm or below also in the cases shown in FIG. 9 and FIG. 10, it is possible to further increase the packing ratio.

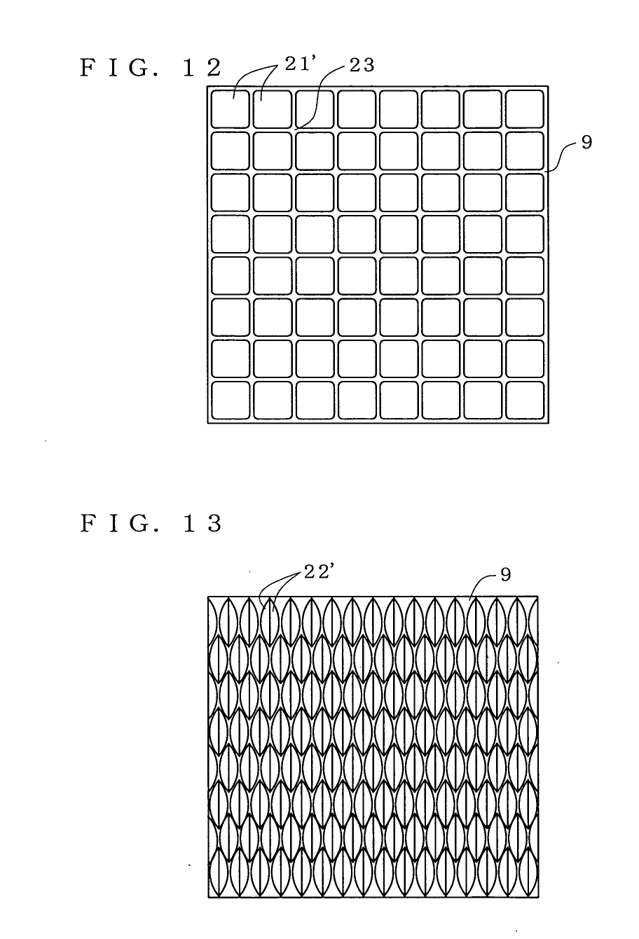

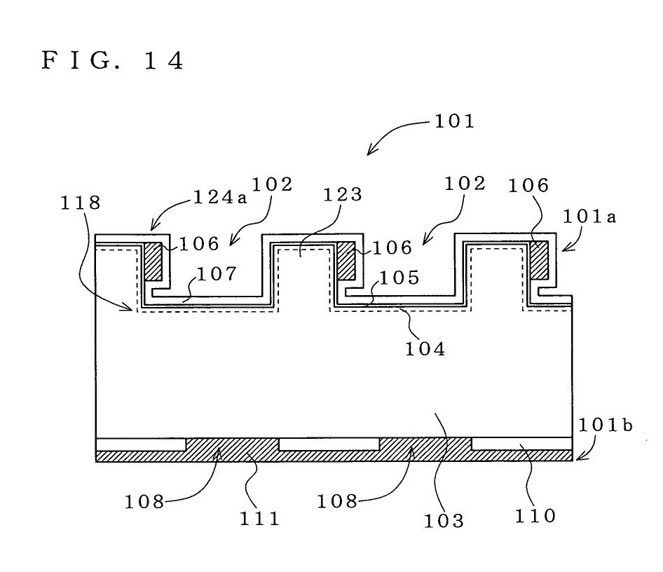

This patent specification conceptually include also a shape of a first segment 21′ shown in FIG. 11 such that the four corners slightly run out from the circumference of the circle, besides the inscribed square having a diagonal length almost equivalent to the diameter D of the disk-formed solar battery cell. Portions of four run-out corners have no entity as the solar battery cell, so that the actual shape of the first segment 21′ will be a quasi-square lacking the four corners. Also this sort of quasi-square is handled as belonging to the concept of “square” if the diagonal length D′ of the virtual square complemented by four corners falls within a range from 0.98 to 1.1 times of the diameter D (The lower limit may be smaller than 1. This will readily be understood considering reduction in size due to cutting width). FIG. 12 shows an exemplary configuration of the solar battery module using thus-obtained first segments 21′. Dead spaces 23 occur at every position where the apexes of the segments 21′ face to each other due to the lack of four corners thereof. The space-filling ratio is therefore reduced to a slight degree, but is causative of only a negligible effect. FIG. 13 shows an exemplary configuration of the solar battery module using second segments 22′. It is obvious that narrowing of the width of the second segments 22′ resulted in a larger number of arranged segments as compared with that in the module shown in FIG. 10.

FIG. 19 shows another exemplary configuration of the solar battery module gathering the bow-formed second segments 22. The configuration has a first-type segment array 30 in which a plurality of second segments 22 are unidirectionally arranged so that the chord portion (cut edge) 22g of one second segment 22 is neighbored on the arc portion 22k of the next second segment 22, and a second-type segment array 40 in which a plurality of second segments 22 are arranged so that the direction of the arrangement of the chord portion 22g and arc portion 22k is inverted from that in the first-type segment array 30. The first-type segment array 30 and the second-type segment array 40 are alternately arranged so that the end portions in the chord-wise direction of every second segment 22 in the second-type segment array 40 is housed in every recessed portion formed between the chord portion 22g of one second segment 22 and the arc portion 22k of the next second segment 22 in the first-type segment array 30. This configuration is successful in achieving a large space-filling ratio similarly to those achievable by the staggered arrangements shown in FIG. 10 and FIG. 13, in further providing a rhythmical design effect closely resembles to aqua flow, and in consequently raising the decorative value when incorporated into buildings.

For the case where the first-type segments and second-type segments obtained by cutting the disk-formed solar battery cells are used, a large dimensional variation in the cut segments consequently needs a larger gap between the adjacent segments in order to absorb the variation, and this inevitably lowers the space-filling ratio by the cells of the solar battery module. Use of a dicer having a disk-formed cutting edge such as that generally used in LSI fabrication process makes it possible to improve, to a considerable degree, the dimensional accuracy of the resultant first-type segments and second-type segments. This consequently makes it possible to bring the adjacent segment more closer, contributing improvement in the space-filling ratio by the cells. In particular for the case where the first-type segments are configured as square cells, improvement in the dimensional accuracy after the cutting can maximize the square-specific geometrical feature such as being capable of filling the surface without causing gaps, and this can largely contribute to increase in the space-filling ratio by the cells.

Although the aforementioned embodiments exemplified the cases where the segments of the solar battery have the finger electrode formed thereon, it is also allowable to use other types of the solar battery. For example, each segment of the solar battery shown in FIG. 14 is configured so as to have a plurality of grooves 102 nearly in parallel to each other formed on the first main surface 124a thereof, wherein each of the grooves has an electrode 106 for output extraction on the inner surface thereof on one side in the width-wise direction. This sort of structure is referred to as OECO (obliquely evaporated contact) structure. Use of the inner surface of the grooves is successful in reducing a projection area of the electrode 6 onto the main surface, thereby the shadowing loss of the battery can considerably be reduced, and a large energy conversion efficiency can be achieved.

In the configuration shown in FIG. 14, on the first main surface 124a of the p-type silicon single crystal, a large number of grooves 102 typically having a width of 100 μm or around and a depth of 100 μm or around are formed in parallel to each other. The first main surface 124a having the grooves formed thereon, has an emitter layer 104 formed therein by thermally diffusing an n-type dopant so as to form a p-n junction portion. On the p-n junction, a thin silicon oxide film 105 which serves as a tunnel insulating film is formed typically by the thermal oxidation process.

On the silicon oxide film 105, the electrode 106 is formed. The electrode 106 is formed by obliquely evaporating an electrode material (metal such as aluminum, for example) onto the inner surface of the grooves in an evaporation apparatus. In the evaporation process, the substrate 101 is placed as being inclined by a predetermined angle or above relative to an evaporation source, so that only one side of the inner surface of the grooves as viewed in the width-wise direction is predominantly deposited with the electrode material (this is a reason of the naming of OECO: any unnecessary deposition of the electrode material possibly deposited on the top surface of convex ridges formed between every adjacent grooves 102, 102 will be removed later using an etching solution such as hydrochloric acid solution). The entire surface of the first main surface 124a of the substrate 101 including the electrode 106 is then covered with a silicon nitride film 107 which functions both as a protective film and anti-reflection film.

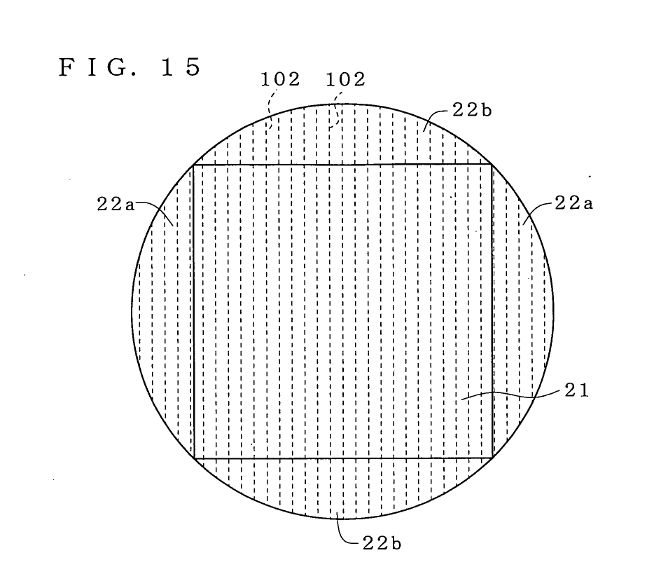

The segment having the OECO structure maximizes the conversion efficiency when the sunlight comes at an optimum angle to the direction of formation of the grooves. Orientation of the grooves differing from segment to segment in one module results in non-uniform output, and a considerable reduction in the power generation efficiency. It is therefore preferable to arrange the segments so that the orientation of the grooves coincide with each other. As shown in FIG. 15, the grooves can be formed on the substrate, in the stage still keeping the disk form, at a time using a grooving edge. The first segment 21 and second segments 22 cut out from the solar battery cell fabricated on this substrate must separately be incorporated into the respective modules considering the orientation of the grooves.

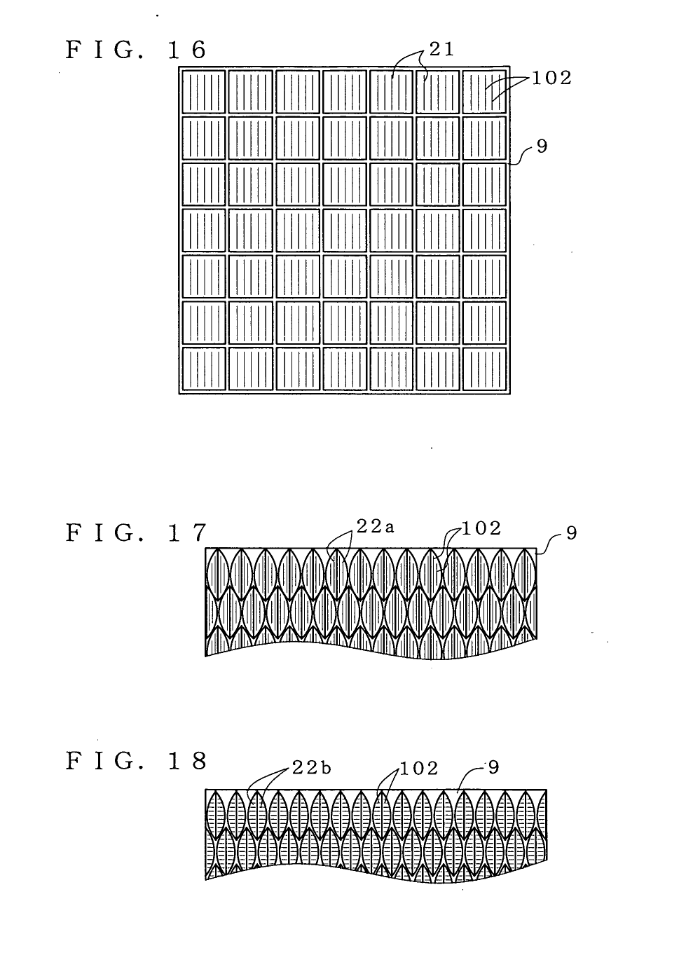

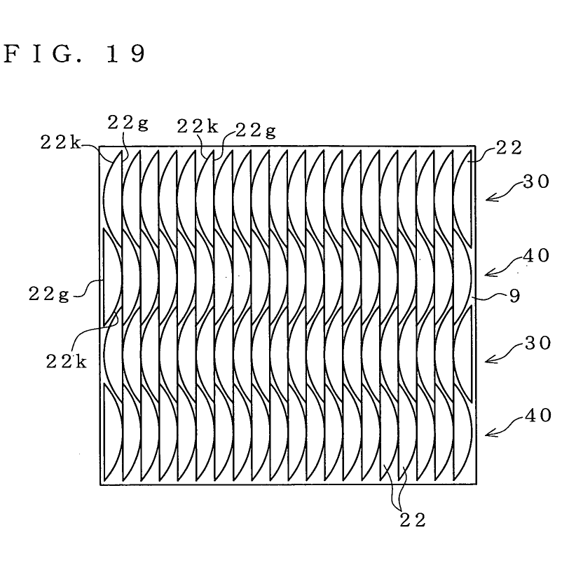

A consideration will now be made on a case where the square-formed first segment 21 is cut as shown in FIG. 8 or FIG. 11. FIG. 16 shows an exemplary solar battery module in which the first segments 21 are arranged so as to uniformly orient the grooves. When the orientation of the grooves 102 is determined in the direction of either edge of the first segment 21, the second segments are produced in two types, that is, the second segments 22a having the grooves 102 in parallel to the chord-like edge, and the second segments 22b having the grooves 102 normal thereto. Therefore, as shown in FIG. 17 and FIG. 18, in two types of second segments 22a, 22b are separately collected, and respectively arranged on the plates 9 so that the orientation of the grooves coincide with each other, so as to produce solar battery modules.

As is obvious from the above, this invention can eliminate loss of single crystal wafer to be used, and can contribute to improvement in the module-packing ratio of the solar battery. It is to be understood that this invention is by no means limited to the aforementioned embodiments, and allows any modifications of these embodiment without departing from the spirit of the invention.

1. A method of fabricating solar battery modules comprising the steps of divisionally producing two or more types of segments differing in the shape from each other from each of disk-formed solar battery substrates, respectively collecting the same types of the segments, and two-dimensionally arranging the segments, by types, to thereby obtain respective solar battery modules.

2. The method of fabricating solar battery modules as claimed in claim 1, wherein all portions of each solar battery substrate are divisionally produced so as to make them belong to any one of the types of the segments.

3. The method of fabricating solar battery modules as claimed in claim 2, wherein the segments are produced by dividing semiconductor single crystal wafers, as the solar battery substrates, directly from the disk form state thereof, and by respectively subjecting thus-divided wafers to cell formation process for forming solar battery cells.

4. The method of fabricating solar battery modules as claimed in claim 2, wherein the segments are produced by subjecting semiconductor single crystal wafers, as the solar battery substrates, in the disk form state thereof to cell formation process for forming solar battery cells respectively in the areas planned to be included later in the segments, and by dividing the wafers after completion of the cell formation process.

5. The method of fabricating solar battery modules as claimed in claim 4, further comprising the steps of:
setting, as planned cutting lines, one pair or two or more pairs of parallel lines (referred to as parallel planned cutting lines, hereinafter) symmetrically arranged with respect to the center of the wafer on a main surface of the semiconductor single crystal wafers;
subjecting the semiconductor single crystal wafers to the cell formation process respectively for a first segment forming area including the center of the wafer and for bow-formed second segment forming areas, which are the residual area besides the first segment forming area, to thereby form the solar battery cells; and
cutting the solar battery cell along the planned cutting lines in the thickness-wise direction thereof.

6. The method of fabricating solar battery modules as claimed in claim 5, wherein only one pair of the parallel planned cutting lines are set on the first main surface of the semiconductor single crystal wafer.

7. The method of fabricating solar battery modules as claimed in claim 6, wherein the distance between each of the parallel planned cutting lines and the center of the wafer is set to R/2, assuming R as the radius of the disk-formed first main surface.

8. The method of fabricating solar battery modules as claimed in claim 6, wherein a plurality of the first segments obtained by cutting the solar battery cell are arranged in a staggered manner so that each of the parallel cut edges produced along the parallel planned cutting lines are adjacent to each other.

9. The method of fabricating solar battery modules as claimed in claim 5, wherein two pairs of the parallel planned cutting lines are set on the first main surface of the semiconductor single crystal wafer.

10. The method of fabricating solar battery modules as claimed in claim 9, wherein two pairs of the parallel planned cutting lines are set in the same length, and the first segment is formed into square.

11. The method of fabricating solar battery modules as claimed in claim 9, wherein the first segments are arranged so as to be aligned in the direction of at least one of the opposed edges out of two pairs of parallel cut edges produced by cutting along the parallel planned cutting lines.

12. The method of fabricating solar battery modules as claimed in claim 5, wherein the second segments obtained by cutting the solar battery cell are paired by opposing the cut edges thereof, and thus-obtained segment pairs are arranged in staggered and parallel manner.

13. The method of fabricating solar battery modules as claimed in claim 5, wherein the second segments are unidirectionally arranged so that the cut edge of one second segment, composing a chord portion thereof, is neighbored on the arc portion of every adjacent second segment to thereby form a first-type segment array, the individual second segments are arranged so that the direction of the arrangement of the chord portion and arc portion is inverted from that in the first-type segment array to thereby form a second-type segment array, and
the first-type segment array and the second-type segment array are alternately arranged so that the end portions in the chord-wise direction of every second segment in the second-type segment array is housed in every recessed portion formed between the chord portion of one second segment and the arc portion of every adjacent second segment in the first-type segment array.

14. The method of fabricating solar battery modules as claimed in claim 8, wherein each of the segments has a plurality of grooves nearly in parallel to each other formed on the first main surface thereof, each of the grooves having an electrode for output extraction on the inner surface thereof on one side in the width-wise direction, and the segments are arranged so that the orientation of the grooves coincide with each other.

15. A solar battery module configured as having solar battery segments arranged in a parallel and staggered manner, each of the segments having a shape remained after cutting the disk-formed solar battery cell along a pair of parallel planned cutting lines symmetrically set with respect to the center of the main surface of the solar battery cell, so as to remove a pair of bow-formed segments from the outer periphery portions, and the segments being arranged so that the parallel cut edges thereof are adjacent to each other.

16. A solar battery module having a plurality of segment pairs arranged in a staggered manner, each of the segment pairs being composed of bow-formed segments having a planar form congruent with each other and being opposed on the chord-like edges thereof, and in a manner so that the chord-like edges are in parallel to each other.

17. A solar battery module having a plurality of bow-formed segment having a planar form congruent with each other, the segments are arranged to form a first-type segment array in which a plurality of segments are unidirectionally arranged so that the chord portion thereof is neighbored on the arc portion of every adjacent segment, and also to form a second-type segment array in which a plurality of segments are arranged so that the direction of the arrangement of the chord portion and arc portion is inverted from that in the first-type segment array, and
the first-type segment array and the second-type segment array are alternately arranged so that the end portions in the chord-wise direction of every segment in the second-type segment array is housed in every recessed portion formed between the chord portion of one segment and the arc portion of every adjacent segment in the first-type segment array.

18. The solar battery module as claimed in claim 15, wherein each of the segments has a plurality of grooves nearly in parallel to each other formed on the first main surface thereof, each of the grooves having an electrode for output extraction on the inner surface thereof on one side in the width-wise direction, and the segments are arranged so that the orientation of the grooves coincide with each other.

19. The method of fabricating solar battery modules as claimed in claim 7, wherein a plurality of the first segments obtained by cutting the solar battery cell are arranged in a staggered manner so that each of the parallel cut edges produced along the parallel planned cutting lines are adjacent to each other.

20. The method of fabricating solar battery modules as claimed in claim 10, wherein the first segments are arranged so as to be aligned in the direction of at least one of the opposed edges out of two pairs of parallel cut edges produced by cutting along the parallel planned cutting lines.

21. The method of fabricating solar battery modules as claimed in claim 11, wherein each of the segments has a plurality of grooves nearly in parallel to each other formed on the first main surface thereof, each of the grooves having an electrode for output extraction on the inner surface thereof on one side in the width-wise direction, and the segments are arranged so that the orientation of the grooves coincide with each other.

22. The method of fabricating solar battery modules as claimed in claim 12, wherein each of the segments has a plurality of grooves nearly in parallel to each other formed on the first main surface thereof, each of the grooves having an electrode for output extraction on the inner surface thereof on one side in the width-wise direction, and the segments are arranged so that the orientation of the grooves coincide with each other.

23. The method of fabricating solar battery modules as claimed in claim 13, wherein each of the segments has a plurality of grooves nearly in parallel to each other formed on the first main surface thereof, each of the grooves having an electrode for output extraction on the inner surface thereof on one side in the width-wise direction, and the segments are arranged so that the orientation of the grooves coincide with each other.

24. The method of fabricating solar battery modules as claimed in claim 19, wherein each of the segments has a plurality of grooves nearly in parallel to each other formed on the first main surface thereof, each of the grooves having an electrode for output extraction on the inner surface thereof on one side in the width-wise direction, and the segments are arranged so that the orientation of the grooves coincide with each other.

25. The method of fabricating solar battery modules as claimed in claim 20, wherein each of the segments has a plurality of grooves nearly in parallel to each other formed on the first main surface thereof, each of the grooves having an electrode for output extraction on the inner surface thereof on one side in the width-wise direction, and the segments are arranged so that the orientation of the grooves coincide with each other.

26. The solar battery module as claimed in claim 16,_wherein each of the segments has a plurality of grooves nearly in parallel to each other formed on the first main surface thereof, each of the grooves having an electrode for output extraction on the inner surface thereof on one side in the width-wise direction, and the segments are arranged so that the orientation of the grooves coincide with each other.

27. The solar battery module as claimed in claim 17,_wherein each of the segments has a plurality of grooves nearly in parallel to each other formed on the first main surface thereof, each of the grooves having an electrode for output extraction on the inner surface thereof on one side in the width-wise direction, and the segments are arranged so that the orientation of the grooves coincide with each other.
